(19) United States
(12) Patent Application Publication
(10) Pub. No.: US 2023/0418995 A1
(43) Pub. Date: Dec. 28, 2023

(54) MULTIPLE SOURCES OF SIGNALS FOR HYBRID METROLOGY USING PHYSICAL MODELING AND MACHINE LEARNING

(71) Applicant: Onto Innovation Inc., Wilmington, MA (US)

(72) Inventors: Jie Li, San Jose, CA (US); Wei Ming Chiew, SINGAPORE (SG); Pei Fen Teh, SINGAPORE (SG); Jingsheng Shi, SINGAPORE (SG)

(73) Assignee: Onto Innovation Inc., Wilmington, MA (US)

(21) Appl. No.: 18/339,973

(22) Filed: Jun. 22, 2023

Related U.S. Application Data
(60) Provisional application No. 63/355,053, filed on Jun. 23, 2022.
(60) Provisional application No. 63/498,475, filed on Apr. 26, 2023.

(51) Int. Cl. G06F 30/20

(52) U.S. Cl. CPC G06F 30/20

(57) ABSTRACT

Physical modeling and machine learning modeling are combined to analyze signals from multiple data sources, including metrology data acquired from different tool sets or at different process steps, and data related to processing equipment, such as sensor data, process parameters, Advanced Process Control (APC) parameters, context data, etc. At least one physical model is generated and used to analyze metrology signals from metrology tools to extract measurement results for key and non-key parameters of a structure on a sample. At least one machine learning model is built and trained to predict parameters of interest based on the extracted measurement results as well as additional data, including raw measured signals, reference data and/or design of experiment (DOE) data, and data from different tool sets or the same tool as used for the physical modeling.

### CROSS REFERENCE TO RELATED APPLICATIONS

This application claims priority under 35 U.S.C. § 119 to U.S. Provisional Application No. 63/355,053, filed Jun. 23, 2022, entitled “METROLOGY SOLUTIONS FOR GATE-ALL-AROUND TRANSISTORS,” and U.S. Provisional Application No. 63/498,475, filed Apr. 26, 2023, entitled “MULTIPLE SOURCES OF SIGNALS FOR HYBRID METROLOGY USING PHYSICAL MODELING AND MACHINE LEARNING,” both of which are assigned to the assignee hereof and are incorporated herein by reference in their entireties.

### FIELD OF THE DISCLOSURE

The subject matter described herein is related generally to metrology, and more particularly to modeling and measuring structures using multiple data sources and a combination of physical modeling and machine learning.

### BACKGROUND

Semiconductor and other similar industries often use metrology, such as optical metrology or X-ray metrology, to provide non-contact evaluation of samples during processing. With optical metrology, for example, a sample under test is illuminated with light, e.g., at a single wavelength or multiple wavelengths. After the light interacts with the sample, the resulting light is detected and analyzed to determine one or more characteristics of the sample.

The analysis typically includes modeling the structure under test. The model may be generated based on the physical properties of the structure, such as the materials and the nominal parameters of the structure, e.g., film thicknesses, optical properties of materials, line and space widths, etc., and is therefore sometimes referred to as a physical model. One or more parameters of the model may be varied and the predicted data may be calculated for each parameter variation based on the model, e.g., using Rigorous Coupled Wave Analysis (RCWA) or other similar techniques. The measured data may be compared to the predicted data for each parameter variation, e.g., in a nonlinear regression process, until a good fit is achieved between the predicted data and the measured data, at which time the fitted parameters are considered an accurate representation of the parameters of the structure under test. Modeling, however, may be time consuming and computationally intensive, and expensive, particularly for small complex features.

### SUMMARY

Physical modeling and machine learning modeling are combined to analyze signals from multiple data sources for hybrid metrology and ecosystem. The signals from data sources include metrology data, which may be acquired from different tool sets or at different process steps, and additional data related to processing equipment, such as sensor data, process parameters, Advanced Process Control (APC) parameters, context data, etc. The predictive power of machine learning is improved through data mining and data fusion of the signals from the multiple data sources. At least one physical model is generated and used to analyze metrology signals from one or more metrology tools to extract measurement results for key and non-key parameters of a structure on a sample. Additionally, at least one machine learning model is built and trained to predict parameters of interest based on the extracted measurement results as well as additional data. The input data for the machine learning model, for example, includes additional data such as the raw measured signals used by the one or more physical models, reference data and/or design of experiment (DOE) data, and data from different tool sets or the same tool as used for the physical modeling, such as process parameters, Advanced Process Control (APC) parameters, context data, and sensor data from production equipment.

In one implementation, a method of characterizing a structure on a sample, includes obtaining measured signals for the structure on the sample from a first metrology device and extracting measurement results from a first physical model for the structure on the sample based on the measured signals. The method further includes determining parameters of interest for the structure on the sample with a machine learning model based on the measurement results extracted from the first physical model. The machine learning model may determine the parameters of interest further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample.

In one implementation, a computer system configured for characterizing a structure on a sample includes at least one processor, where the at least one processor is configured to obtain measured signals for the structure on the sample from a first metrology device and extract measurement results from a first physical model for the structure on the sample based on the measured signals. The at least one processor is further configured to determine parameters of interest for the structure on the sample with a machine learning model based on the measurement results extracted from the first physical model. The machine learning model may determine the parameters of interest further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample.

In one implementation, a system configured for characterizing a structure on a sample, includes means for obtaining measured signals for the structure on the sample from a first metrology device and means for extracting measurement results from a first physical model for the structure on the sample based on the measured signals. The system further includes means for determining parameters of interest for the structure on the sample with a machine learning model based on the measurement results extracted from the first physical model. The machine learning model may determine the parameters of interest further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample.

In one implementation, a method of characterizing a structure on a sample, includes obtaining pre-process step measured signals from a metrology device for the structure on the sample at a pre-process step, and obtaining post-process step measured signals from the metrology device for the structure on the sample at a post-process step. The method further includes extracting post-process measurement results from a post-process physical model for the structure on the sample based on the post-process step measured signals, and generating pre-process step data based at least on the pre-process step measured signals. The method further includes determining parameters of interest for the structure on the sample with a machine learning model based on the post-process measurement results extracted from the post-process physical model, and the pre-process step data.

In one implementation, a computer system configured for characterizing a structure on a sample includes at least one processor, where the at least one processor is configured to obtain pre-process step measured signals from a metrology device for the structure on the sample at a pre-process step, and obtain post-process step measured signals from the metrology device for the structure on the sample at a post-process step. The at least one processor is further configured to extract post-process measurement results from a post-process physical model for the structure on the sample based on the post-process step measured signals, and generate pre-process step data based at least on the pre-process step measured signals. The at least one processor is further configured to determine parameters of interest for the structure on the sample with a machine learning model based on the post-process measurement results extracted from the post-process physical model, and the pre-process step data.

In one implementation, a system configured for characterizing a structure on a sample, includes means for obtaining pre-process step measured signals from a metrology device for the structure on the sample at a pre-process step, and means for obtaining post-process step measured signals from the metrology device for the structure on the sample at a post-process step. The system further includes means for extracting post-process measurement results from a post-process physical model for the structure on the sample based on the post-process step measured signals, and means for generating pre-process step data based at least on the pre-process step measured signals. The system further includes means for determining parameters of interest for the structure on the sample with a machine learning model based on the post-process measurement results extracted from the post-process physical model, and the pre-process step data.

In one implementation, a method of characterizing a structure on a sample, includes obtaining measured signals for one or more reference samples for the structure from a first metrology device and generating a first physical model to extract measurement results for the structure on the sample, where the first physical model is generated based on the measured signals for the one or more reference samples from the first metrology device. The method further includes generating a machine learning model to predict parameters of interest for the structure on the sample. The machine learning model is generated based on the measurement results extracted by the first physical model and at least one of reference data and design of experiment information. The machine learning model may be generated further based on at least one of: data from measured signals from the first metrology device not used in generating the first physical model, second measured signals obtained for the one or more reference samples from a second metrology device, process parameters used to generate the one or more reference samples, Advanced Process Control (APC) parameters used to generate the one or more reference samples, context data for the one or more reference samples, and sensor data from production equipment used to generate the one or more reference samples.

In one implementation, a computer system configured for characterizing a structure on a sample includes at least one processor, where the at least one processor is configured to obtain measured signals for one or more reference samples for the structure from a first metrology device and generate a first physical model to extract measurement results for the structure on the sample, where the first physical model is generated based on the measured signals for the one or more reference samples from the first metrology device. The at least one processor is further configured to generate a machine learning model to predict parameters of interest for the structure on the sample. The machine learning model is generated based on the measurement results extracted by the first physical model and at least one of reference data and design of experiment information. The machine learning model may be generated further based on at least one of: data from measured signals from the first metrology device not used in generating the first physical model, second measured signals obtained for the one or more reference samples from a second metrology device, process parameters used to generate the one or more reference samples, Advanced Process Control (APC) parameters used to generate the one or more reference samples, context data for the one or more reference samples, and sensor data from production equipment used to generate the one or more reference samples.

In one implementation, a system configured for characterizing a structure on a sample, includes means for obtaining measured signals for one or more reference samples for the structure from a first metrology device and means for generating a first physical model to extract measurement results for the structure on the sample, where the first physical model is generated based on the measured signals for the one or more reference samples from the first metrology device. The system further includes means for generating a machine learning model to predict parameters of interest for the structure on the sample. The machine learning model is generated based on the measurement results extracted by the first physical model and at least one of reference data and design of experiment information. The machine learning model may be generated further based on at least one of: data from measured signals from the first metrology device not used in generating the first physical model, second measured signals obtained for the one or more reference samples from a second metrology device, process parameters used to generate the one or more reference samples, Advanced Process Control (APC) parameters used to generate the one or more reference samples, context data for the one or more reference samples, and sensor data from production equipment used to generate the one or more reference samples.

In one implementation, a method of characterizing a structure on a sample, includes obtaining pre-process step measured signals from a metrology device for one or more reference samples for the structure at a pre-process step and obtaining post-process step measured signals from the metrology device for the one or more reference samples for the structure at a post-process step. The method further includes generating a post-process physical model to extract post-process measurement results for the structure on the reference sample, where the post-process physical model is generated based on the post-process step measured signals, and generating pre-process step data based at least on the pre-process step measured signals. The method further includes generating a machine learning model to predict parameters of interest for the structure on the sample. The machine learning model is generated based on the post-process measurement results extracted by the post-process physical model and at least one of reference data and design of experiment information, and the pre-process step data.

In one implementation, a computer system configured for characterizing a structure on a sample includes at least one processor, where the at least one processor is configured to obtain pre-process step measured signals from a metrology device for one or more reference samples for the structure at a pre-process step and obtain post-process step measured signals from the metrology device for the one or more reference samples for the structure at a post-process step. The at least one processor is further configured to generate a post-process physical model to extract post-process measurement results for the structure on the reference sample, where the post-process physical model is generated based on the post-process step measured signals, and generate pre-process step data based at least on the pre-process step measured signals. The at least one processor is further configured to generate a machine learning model to predict parameters of interest for the structure on the sample. The machine learning model is generated based on the post-process measurement results extracted by the post-process physical model and at least one of reference data and the design of experiment information, and the pre-process step data.

In one implementation, a system configured for characterizing a structure on a sample, includes means for obtaining pre-process step measured signals from a metrology device for one or more reference samples for the structure at a pre-process step and means for obtaining post-process step measured signals from the metrology device for the one or more reference samples for the structure at a post-process step. The system further includes means for generating a post-process physical model to extract post-process measurement results for the structure on the reference sample, where the post-process physical model is generated based on the post-process step measured signals, and means for generating pre-process step data based at least on the pre-process step measured signals. The system further includes means for generating a machine learning model to predict parameters of interest for the structure on the sample. The machine learning model is generated based on the post-process measurement results extracted by the post-process physical model and at least one of reference data and design of experiment information, and the pre-process step data.

### BRIEF DESCRIPTION OF THE DRAWINGS

FIG. 1 illustrates a schematic view of a metrology device that may be used to characterize a sample as discussed herein.

FIG. 2 illustrates a workflow for offline recipe creation in accordance with a first example scenario with signals collected from multiple data sources, including different tools and/or sources.

FIG. 3 illustrates a workflow for inline measurement in accordance with the first example scenario with signals collected from multiple data sources, including different tools and/or sources.

FIG. 4 illustrates a workflow for offline recipe creation in accordance with a second example scenario with signals collected from multiple data sources, including different manufacturing process steps.

FIG. 5 illustrates a workflow for inline measurement in accordance with the second example scenario with signals collected from multiple data sources, including different manufacturing process steps.

FIGS. 6-9 illustrates flowcharts depicting methods for characterizing a structure on a sample.

### DETAILED DESCRIPTION

During fabrication of semiconductor devices and similar devices it is often necessary to monitor the fabrication process by non-destructively measuring the devices. One type of metrology that may be used for non-destructive measurement of samples during processing is optical metrology, which may use a single wavelength or multiple wavelengths, and may include, e.g., ellipsometry, reflectometry, Fourier Transform infrared spectroscopy (FTIR), etc. Other types of metrology may also be used, including X-ray metrology, opto-acoustic metrology, electron beam (E-beam) metrology, etc.

Optical metrology, such as thin film metrology and Optical Critical Dimension (OCD) metrology, and other types of metrology, sometimes use physical modeling techniques to generate predicted data of a sample that is compared with the measured data from the sample. With physical modeling techniques, a model of the sample is generated that includes key and non-key parameters. The model may be based on nominal parameters of the sample and may include one or more variable parameters, such as layer thicknesses, line widths, space widths, sidewall angles, material properties, etc., that may be varied over a desired range, e.g., depending on the process parameters used to fabricate the sample under test. The model may further include parameters related to the tool set, e.g., characteristics of the optical system used by the metrology device. Predicted data may be calculated based on the parameters of the physical model, including variations of the variable parameters, and characteristics of the metrology device using analytical or semi-analytical methods, such as effective medium theory (EMT), finite-difference time-domain (FDTD), transfer matrix method (TMM), the Fourier modal method (FMM)/rigorous coupled-wave analysis (RCWA), the finite element method (FEM), etc. Measured data acquired from the sample by the metrology device is compared to the predicted data for different parameter variations, e.g., in a nonlinear regression process, until a best fit is achieved, at which time the values of the fitted parameters are considered to be an accurate representation of the parameters of the sample.

Conventionally, modeling requires that preliminary structural and material information is known about the sample in order to generate an accurate representative model of the sample, including one or more variable parameters. For example, the preliminary structural and material information for a sample may include the type of structure and a physical description of the sample with nominal values for various parameters, such as layer thicknesses, line widths, space widths, sidewall angles, material properties, etc., along with a range within which these parameters may vary. The model may further include one or parameters that are not variable, i.e., are not expected to change in the sample by a significant amount during manufacturing. The variable parameters of the model are adjusted and the predicted data may be produced in real time during the non-linear regression process, or a library may be pre-generated. Thus, modeling applies physical constraints in the analysis and accordingly offers a high level of fidelity for the measurement results. However, modeling has a high computation cost due to the physical calculations necessary to generate the predicted data. For example, modeling complex 3D structures suffers from a slow time to solution (TTS) and modeling accuracy may be degraded due to difficulties in fitting data for complex structures.

Another technique that may be used to generate predicted data for a sample based on measured data acquired from a sample by a metrology device is machine learning. Machine learning algorithms that may be used for metrology, for example, may include, but are not limited to, linear regression, neural networks, deep learning, convolution neural-network (CNN), ensemble methods, support vector machine (SVM), random forest, etc., or combination of multiple models in sequential mode and/or parallel mode. Machine learning does not require a physical model of the sample. Instead, reference data, e.g., measured data acquired from one or more reference samples by the metrology device, is obtained, along with the values of structure parameters of interest, and is used to generate and train a machine learning model. The machine learning models are automatically trained using the reference data and the known values of the structure parameters to find relevant data features and learn the intrinsic relationship and connections between input and output features in order to make decisions and predictions for new data. The benefit of the use of machine learning is fast time to solution (TTS) and minimal requirements for computing resources. However, machine learning requires a large amount of reference data which is costly and time-consuming to obtain. Without a large amount of reference data, the machine learning model may suffer from overfitting due to the lack of physical constraints.

As semiconductor devices continue to shrink, metrology budgets become tighter. Additionally, complex 3D structures are being adopted more frequently to enable continued device scaling. Semiconductor technology advancements, such as the use of complex 3D structures, place additional challenges on metrology due to increased modeling complexities and parameter correlation, and reduced sensitivity. Signals from a single metrology tool or source, for example, may not have sufficient sensitivities to measure parameters of interest accurately for semiconductor process quality control. Ultimately there may be no single metrology tool that can handle all metrology requirements for most advanced semiconductor devices.

As discussed herein, with the use of data collected from multiple data sources, e.g., from multiple tool sets and/or process steps and the use of additional data related to the samples that is collected from metrology and/or production equipment, such as sensor data, a computationally efficient data analysis method may fuse the multiple data sources and produce more accurate and consistent measurement results than what can be provided by any individual data source. The analysis method may be flexible to accommodate a variety of data of different nature, while at the same time maximize usage of existing well-developed techniques, such as physical modeling or machine learning, for each type of data source and synergize the strength of individual metrology technology.

As discussed herein, physical modeling and machine learning are combined to analyze multiple sources of data for hybrid metrology and ecosystem. The method described herein creates predictive power through data mining and data fusion from multiple data sources, e.g., multiple metrology tool sets, sample data from multiple process steps, metrology equipment parameters, and production equipment parameters. By way of example, at least one physical model may be used to analyze metrology signals from one or more metrology tools, such as spectroscopic ellipsometer, spectroscopic reflectometer, X-ray metrology, opto-acoustic metrology, Fourier Transform infrared spectroscopy (FTIR), E-beam metrology, etc., to extract measurement results for key and non-key parameters of a sample. Additionally, at least one machine learning model may be built and trained to predict parameters of interest. The machine learning model may use input data from one or more of: the measurement results (key and non-key parameters) from the one or more physical models; the raw signals used for the one or more physical models and optionally the misfit; data sources from different tool sets, or the same tool, but not included in physical modeling; process parameters, Advanced Process Control (APC) parameters, context data; and sensor data from production equipment. The in-line measurement of a sample uses the one or more physical models, and trained machine learning model to make predictions for sample parameters of interest based on data acquired from the multiple data sources.

The proposed techniques can be used to combine and analyze multiple sources of data in an efficient and flexible way of synergizing physical modeling and machine learning with controllable computation cost and software and modeling complexities, thus provides most viable solutions with manageable time to solution (TTS) and improved final results and overall metrology performance. The approach is also universal and can be applied to measurements of any devices, OCD, thin film, or other types of targets.

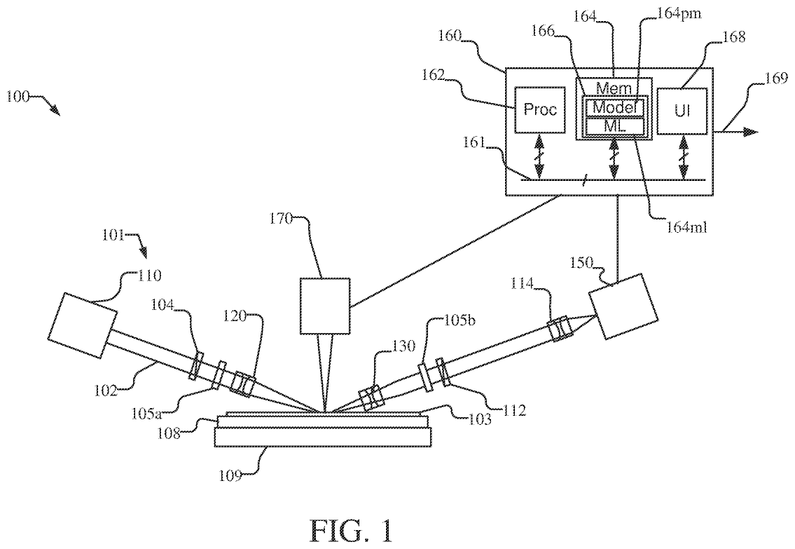

FIG. 1, by way of example, illustrates a schematic view of a metrology device 100 that may be used to characterize a structure on a sample, as described herein. The metrology device 100 may be configured to perform one or more types of measurements, such as, e.g., spectroscopic reflectometry, spectroscopic ellipsometry (including Mueller matrix ellipsometry), spectroscopic scatterometry, overlay scatterometry, interferometry, opto-acoustic metrology, E-beam metrology, X-ray metrology, FTIR measurements, etc. of a sample 103. Metrology device 100, for example, may include a first metrology tool 101 and a second metrology tool 170, but may include additional metrology tools, or may be coupled to receive sample data measured by a separate metrology tool. It should be understood that metrology device 100 is illustrated as one example configuration for a metrology device, and that if desired other configurations and other metrology devices may be used.

Metrology device 100 includes an oblique incidence metrology tool 101 that includes a light source 110 that produces light 102. The light 102, for example, may be UV-visible light with wavelengths, e.g., between 200 nm and 1000 nm. The light 102 produced by light source 110 may include a range of wavelengths, i.e., continuous range or a plurality of discrete wavelengths, or may be a single wavelength. The metrology device 100 includes focusing optics 120 and 130 that focus and receive the light and direct the light to be obliquely incident on a top surface of the sample 103. The optics 120, 130 may be refractive, reflective, or a combination thereof and may be an objective lens.

The reflected light may be focused by lens 114 and received by a detector 150. The detector 150 may be a conventional charge coupled device (CCD), photodiode array, CMOS, or similar type of detector. The detector 150 may be, e.g., a spectrometer if broadband light is used, and detector 150, for example, may generate a spectral signal as a function of wavelength. A spectrometer may be used to disperse the full spectrum of the received light into spectral components across an array of detector pixels. One or more polarizing elements may be in the beam path of the metrology device 100. For example, metrology device 100 may include one or both (or none) of one or more polarizing elements 104 in the beam path before the sample 103, and a polarizing element (analyzer) 112 in the beam path after the sample 103, and may include one or more additional elements 105a and 105b, such as a compensator or photoelastic modulator, which may be before, after, or both before and after the sample 103. With the use of a spectroscopic ellipsometer using dual rotating compensators, between polarizing elements 104 and 112 and the sample, a full Mueller matrix may be measured.

Metrology device 100 may include or may be coupled to additional metrology devices. For example, as illustrated, metrology device 100 may include a second, normal incidence, metrology tool 170. The second metrology tool 170, by way of example, may be configured for spectroscopic reflectometry, spectroscopic scatterometry, overlay scatterometry, interferometry, E-beam metrology, X-ray metrology, FTIR measurements, etc. In some implementations, the metrology device 100 may include additional tools, e.g., a third (or more) metrology tools. In some implementations, additional metrology tools may be separate from the metrology device 100.

Metrology device 100 further includes at least one computing system 160 that is configured to characterize one or more parameters of the sample 103 using the methods described herein. The at least one computing system 160 is coupled to the first metrology tool 101, e.g., detector 150, and the second metrology tool 170 and any additional metrology tools, if present, to receive the metrology data acquired during measurement of the structure of the sample 103. The acquisition of data may be performed during a pre-process fabrication step as well as a post-process fabrication step. The at least one computing system 160, for example, may be a workstation, a personal computer, central processing unit or other adequate computer system, or multiple systems.

It should be understood that the at least one computing system 160 may be a single computer system or multiple separate or linked computer systems, which may be interchangeably referred to herein as computing system 160, or at least one computing system 160. The computing system 160 may be included in or is connected to or otherwise associated with metrology device 100, and any additional metrology tools. Different subsystems of the metrology device 100 may each include a computing system that is configured for carrying out steps associated with the associated subsystem. The computing system 160, for example, may control the positioning of the sample 103, e.g., by controlling movement of a stage 109 that is coupled to the chuck. The stage 109, for example, may be capable of horizontal motion in either Cartesian (i.e., X and Y) coordinates, or Polar (i.e., R and θ) coordinates or some combination of the two. The stage may also be capable of vertical motion along the Z coordinate. The computing system 160 may further control the operation of the chuck 108 to hold or release the sample 103. The computing system 160 may further control or monitor the rotation of one or more polarizing elements 104, 112, or additional elements 105a, 105b, etc.

The computing system 160 may be communicatively coupled to the detector 150 in the first metrology tool 101 and to a detector in the second metrology tool 170 (if present) in any manner known in the art. For example, the at least one computing system 160 may be coupled to a separate computing system that is associated with the detector 150. The computing system 160 may be configured to receive and/or acquire metrology data, e.g., from the detector 150, as well as controllers polarizing elements 104, 112, and additional elements 105a, 105b, etc., as well as components of the second metrology tool 170, via a transmission medium that may include wireline and/or wireless portions. The transmission medium, thus, may serve as a data link between the computing system 160 and other subsystems of the metrology device 100. The computing system 160 may be further configured to receive and/or acquire additional information about the sample and one or more subsystems of the first metrology tool 101 and production equipment, e.g., from a user interface (UI) 168 or via a transmission medium that may include wireline and/or wireless portions.

The computing system 160, which includes at least one processor 162 with memory 164, as well as the UI 168, which are communicatively coupled via a bus 161. The memory 164 or other non-transitory computer-usable storage medium, includes computer-readable program code 166 embodied thereof and may be used by the computing system 160 for causing the at least one computing system 160 to control the metrology device 100 and to perform the functions including the techniques and analysis described herein. For example, as illustrated, memory 164 may include instructions for causing the processor 162 to perform both modeling and machine learning, and in some implementations, may employ feedforward and/or feedback, as discussed herein. The data structures and software code for automatically implementing one or more acts described in this detailed description can be implemented by one of ordinary skill in the art in light of the present disclosure and stored, e.g., on a computer-usable storage medium, e.g., memory 164, which may be any device or medium that can store code and/or data for use by a computer system, such as the computing system 160. The computer-usable storage medium may be, but is not limited to, include read-only memory, a random access memory, magnetic and optical storage devices such as disk drives, magnetic tape, etc. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described.

The computing system 160, for example, may be configured to obtain data for reference samples from multiple data sources, including from one or both metrology tools 101 and 170, and any desired additional metrology tools, as well as data related to the sample, such as reference data and/or DOE data, and data related to the metrology tools and/processing equipment, such as process parameters, Advanced Parameter Control (APC) parameters, context data, and sensor data from production equipment. The computing system 160 may be configured to generate one or more physical models (Model 164pm) for the sample, based on measured data from one or more reference samples and optionally additional information related to the sample and/or processing equipment, and generate and train one or more machine learning models (ML 164ml) for the sample, based on measurement results extracted from the one or more physical models and data, as discussed herein. In some implementations, a different computing system and/or different metrology device(s) may be used to acquire the metrology data and additional information from training samples and generate one or more physical models (Model 164pm) and/or generate and train one or more machine learning models (ML 164ml), and the resulting physical models and/or trained machine learning models (or portions thereof) may be provided to the computing system 160, e.g., via the computer-readable program code 166 on non-transitory computer-usable storage medium, such as memory 164.

The computing system 160 may be additionally or alternatively used to acquire data from a test sample from multiple data sources. The data may be the same type used to generate the physical model(s) and to generate and train the machine learning model(s) discussed above, and the test sample has the same structure as the reference samples. The computing system 160 may be configured to determine one or more parameters of interest for the sample using the data from multiple sources and the one or more physical models (Model 164pm) and the one or more trained machine learning models (ML 164ml), as discussed herein.

The results from the analysis of the data may be reported, e.g., stored in memory 164 associated with the sample 103 and/or indicated to a user via UI 168, an alarm or other output device. Moreover, the results from the analysis may be reported and fed forward or back to the process equipment to adjust the appropriate fabrication steps to compensate for any detected variances in the fabrication process. The computing system 160, for example, may include a communication port 169 that may be any type of communication connection, such as to the internet or any other computer network. The communication port 169 may be used to receive instructions that are used to program the computing system 160 to perform any one or more of the functions described herein and/or to export signals, e.g., with measurement results and/or instructions, to another system, such as external process tools, in a feedforward or feedback process in order to adjust a process parameter associated with a fabrication process step of the samples based on the measurement results.

As discussed herein, for characterizing sample, (1) at least one physical based model is built to analyze metrology signals from one tool or multiple tools such as spectroscopic ellipsometry (SE), spectroscopic reflectometry (SR), X-ray, E-beam, opto-acoustic data, Fourier-transform infrared spectroscopy (FTIR) etc., and from one or more sources to extract measurement results for key and non-key parameters. Additionally, (2) at least one machine learning model is built and trained to predict parameters of interest. The machine learning model may take one of more of the following data as inputs: a) the measurement results (key and non-key parameters) from the physical model(s) from 1); b) the raw signal for physical model(s) from (1) and optionally the misfit; data sources from different tool sets, or the same tool in (1) but not included in physical modeling; process parameters, APC parameters, context data; and sensor data from production equipment. Additionally, (3) in line measurement of the sample may be performed using the physical model(s) and machine learning model(s) created and trained offline to make predictions the parameters of interest based on data from multiple data sources.

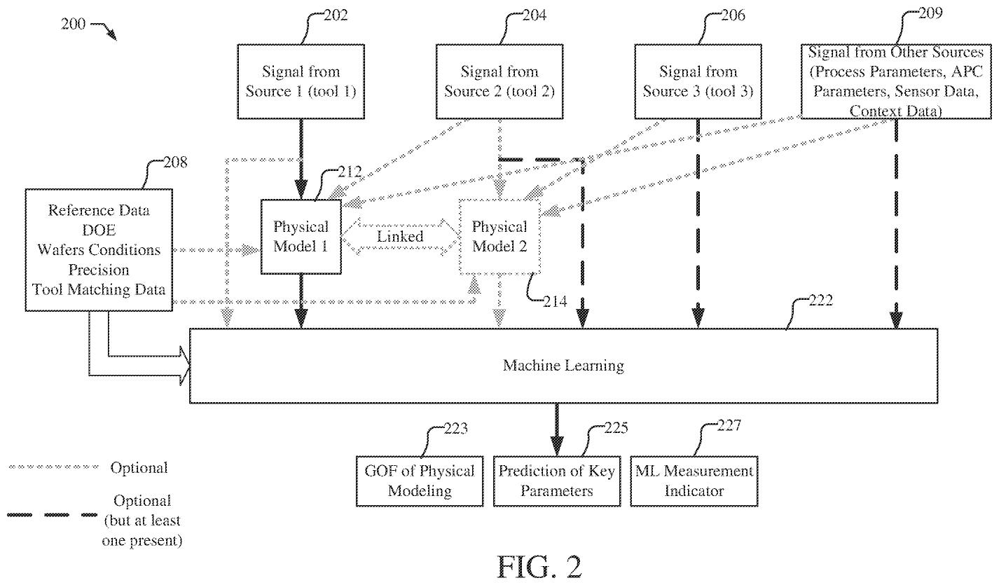

FIG. 2, by way of example, illustrates a workflow 200 for offline recipe creation, e.g., generating one or more physical models and one or more machine learning models, in accordance with a first example scenario with data collected from multiple data sources, e.g., different tools and/or sources. In FIG. 2, solid black arrows indicate processes that are used in the workflow 200, dashed black arrows indicate processes that are optional, but at least one is present, while dotted grey arrows indicate processes that are optional.

As illustrated, measured signals 202 from one or more reference samples are collected from a first data source or tool (Source 1). The measured signals 202 may be collected from any desired metrology device, such as metrology tool 101 shown in FIG. 1, or from any other desired type of metrology device.

Additionally, data is acquired from one or more additional data sources. For example, in some implementations, measured signals 204 and 206 from the one or more reference samples may be collected from one or more additional sources or tools, e.g., illustrated as a second source or tool (Source 2) and a third source or tool (Source 3). The additional measured signals 204, for example, may be collected from a metrology device that is different than Source 1, such as metrology tool 170 shown in FIG. 1, or from any other desired type of metrology device, and the measured signals 206 may be collected from a metrology device that is different than Source 1 and Source 2, such as a different type of measurement from either of metrology tools 101 or 170 or from any other desired type of metrology device. Additional data 208 related to the reference samples may be collected and used as training data for one or more machine learning models 222, as illustrated with the block arrow. The additional data 208, for example, may include reference data for the sample and the DOE data. Reference data, for example, may be measured signals acquired from one or more reference samples by the metrology device along with the values of structure parameters of interest typically provided by CD-AFM (atomic force microscopy), CD-SEM (scanning electron microscopy) or TEM (Transmission electron microscopy). DOE data, for example, may be measured data from a set of reference samples processed with intentionally introduced skew conditions so that the structure parameters of interest are varied by the skewed process conditions with known patterns. Reference data and/or DOE data may be used as training data set to train machine learning models to find relevant data features and learn the intrinsic relationship and connections between input and output features in order to make decisions and predictions for new data. In some implementations, the additional data 208 related to the reference samples may further include wafer conditions, precision, tool matching data, etc. Precision data, for example, are repeatedly measured data from the same target at multiple times from a same instance of tool. Precision metric is another metrology key performance indicator (KPI) that indicates the consistency of measured results from multiple runs for the same sample. Tool matching data, for example, are measured data from the same target from multiple instances of tool of same tool type. Tool matching metric is another metrology KPI that indicates the consistency of measured results from different tools of same type for the same sample. Measurement accuracy (evaluated by matching to reference values provided from CD-AFM, CD-SEM, TEM etc. and/or consistence to DOE conditions), precision and tool matching are typical metrology KPIs. If precision and tool matching data are provided, physical modeling or machine learning models may be optimized to not only closely match reference values, but also to predict consistent results for a same sample with measured signals from multiple runs from the same tool or from different tools of same type.

Further, in some implementations, additional data signals 209 may be used as inputs for physical models or input features for machine learning models. The additional data signals 209, for example, may be related to the sources (e.g., Source 1, Source 2, and Source 3), may be obtained, such as process parameters, Advanced Process Control (APC) parameters, context data; and sensor data from production equipment. By way of example, some process control parameters, e.g., substrate temperature and chemical concentration for wet etch can impact etch rate (how fast materials are removed from surface of the wafer), and etch rate is one of the important factors to determine etch depth and CD profile. Some of these parameters, such as temperature, are measured by sensors from production equipment. Other parameters, such as etch time, name of etch chambers, are user-controlled parameters. Name of the etch chambers is an example of context data. Since each etch chamber has its own characteristic distribution of etch profiles across a wafer, knowing this information may help machine learning predict a correct wafer map. An example of APC parameters is atomic force microscope (AFM) results measured from the same sample at different process steps that contain relevant information, e.g., non-key parameters for the structure of interests. Adding the non-key parameters as machine learning input features can help improve machine learning robustness on predicting key parameters. Adding all these relevant parameters as machine learning input features may provide additional information that helps determine structure parameters of interest controlled by these process parameters and conditions.

The measured signals and data from the multiple data sources may be used to generate one or more physical models. For example, as illustrated with the solid black arrow, the measured signals 202 from the first source (Source 1) may be used to generate a first physical model 212 of the sample. A physical model of a sample, for example, is created based on known geometry, nominal values, and materials of the structure. The measured signals 202 may be used to generate the first physical model 212 by providing data from which measurement results are extracted, and the first physical model 212 may be adjusted and optimized so that the calculated signals are a good fit to the measured signals and a good match between the extracted measurement results and the known parameters of the reference samples is achieved. In some implementations, additional data may be used to assist in generating the first physical model 212. For example, as illustrated with the dotted grey arrow, additional data 208, such as the reference data and/or DOE, and optionally the wafer conditions, precision, and tool matching data, may also be used to assist in the generation of the first physical model 212. Additionally, as illustrated with the grey dotted arrow, the data signals 209 may be used to assist in the generation of the first physical model 212. In another example, as illustrated with the dotted grey arrow, the measured signals 204 from the second source (Source 2) may be used to assist in the generation of the first physical model 212 of the sample. In some implementations, both additional data 208 and measured signals 204 may be used to assist in the generation of the first physical model 212.

In some implementations, multiple physical models may be generated. For example, as illustrated with the grey dotted arrows and grey dotted box, a second physical model 214 may be generated based on measured signals 204 from the second source (Source 2). In some implementations, additional data may be used to generate the second physical model 214. For example, as illustrated by the dotted grey arrow, additional data 208, such as the reference data and/or DOE, and optionally the wafer conditions, precision, and tool matching data, may also be used to assist in the generation of the second physical model 214. In another example, as illustrated with the dotted grey arrow, the measured signals 206 from the third source (Source 3) may be used to assist in the generation of the second physical model 214 of the sample. In some implementations, both additional data 208 and measured signals 206 may be used to assist in the generation of the second physical model 214. Additionally, as illustrated with the grey dotted arrow, the data signals 209 may be used to assist in the generation of the second physical model 214. Moreover, the multiple physical models may be optimized independently or co-optimized. For example, in some implementations, as illustrated with dotted grey lines, the first physical model 212 and the second physical model 214 may be linked so that at least some parameters may be coupled across the physical models 212 and 214 and the combined parameter space may be searched to fit the measured signals from one or multiple data sources. The first physical model 212, and optionally, the second physical model 214, may be configured to provide goodness of fit 223 of the physical modeling.

One or more machine learning models 222 is built and trained using the multiple data sources to predict parameters of interest 225. A machine learning measurement indicator 227 can be developed and reported together with the goodness of fit 223 from the physical modeling to indicate the measurement quality of the recipe synergized from physical modeling and machine learning. As illustrated with the solid black arrows, the machine learning model 222 is built using the measurement results extracted by the first physical model 212 as input features. As indicated with the dashed black arrows, the input features of machine learning model 222 may additionally include at least one of measured signals 204 from the one or more reference samples collected from the second source (Source 2), measured signals 206 from the one or more reference samples collected from the third source (Source 3), additional data signals 209, the measurement results extracted by the second physical model 214, or any combination thereof. In some implementations, as illustrated with the dotted grey arrow, the input features of the machine learning model 222 optionally may include the measured signals 202 from the one or more reference samples collected from the first source (Source 1). In some implementations, the input features from the measured signals 202 may include data from measured signals, such as at least one data channel or at least one data chunk, that are not used in generating the first physical model 212. For example, in general, a data channel may be a measurement subsystem that is defined by at least one of the energy source, such as the light source, the optical path directed by optical parts, the detector, or any combination thereof, and a data chunk may be a subset of wavelengths (e.g., as used in spectroscopic metrology), frequencies (e.g., as used in frequency resolved metrology), angles (e.g., as used in angular resolved metrology), time span (e.g., as used in time resolved metrology), or any combination of the above from a full data set provided by a data channel. For example, the first metrology device may collect normal incidence signals and oblique incidence spectroscopic ellipsometer (SE) signals. The SE signals may be used to generate the first physical model 212, but the normal incidence signals may not be used, as it may be difficult to fit the normal incidence signals. The normal incidence signals, thus, may be a data channel that is used as data for machine learning model 222 input features, in addition to the physical modeling results produced from a different data channel, e.g., the SE signals. In another example, the same data channel may be split into multiple data chunks, e.g., signals from different wavelength ranges, and some data chunks may be difficult to fit using physical modeling, but may be used as data for the machine learning model 222 input features.

The machine learning model 222 is trained with at least a portion of the data 208, such as the reference data and/or DOE, and optionally the wafer conditions, precision, and tool matching data. The data 208 is training data and used for offline training. For example, reference data may be a set of signals (e.g., including any of the measurement results from the first physical model 212, measured signals 204, measured signals 206, additional data signals 209, and measured signals 202) with labels (e.g., values of key parameter provided by other metrology systems such as CD-SEM, TEM CD-AFM). During training of the machine learning model 222, the set of signals from the reference data are used as machine learning input features, and based on these input features, the machine learning model 222 makes predictions for the key parameters. The machine learning model 222 is trained to learn and make predictions for key parameters that match the labels of the reference data. The DOE from data 208 are a set of signals (e.g., including any of the measurement results from the first physical model 212, measured signals 204, measured signals 206, additional data signals 209, and measured signals 202) measured from reference samples processed with intentionally introduced skew conditions. During machine learning training, the machine learning model 222 takes the signals from DOE data as input features and make predictions for key parameters. The machine learning model 222 is trained so that the predicted key parameter values follow the expected skew pattern based on the process skew conditions. Precision data from data 208 are measured signals (e.g., including any of the measurement results from the first physical model 212, measured signals 204, measured signals 206, additional data signals 209, and measured signals 202) from the same sample but on multiple runs from same metrology tool. Similarly, tool matching data from data 208 are signals (e.g., including any of the measurement results from the first physical model 212, measured signals 204, measured signals 206, additional data signals 209, and measured signals 202) from the same sample but measured from different instances of metrology tools of same type. The machine learning model 222 takes precision and tool matching data as input features and makes predictions. The machine learning model 222 is trained so that the predicted values for key parameters are consistent for the signals measured from the same samples but from different runs or different tools. The machine learning model 222 can be trained so that all the criteria, matching to reference values, DOE skew conditions, high precision and consistent tool matching are met at the same time if all these data are provided during training.

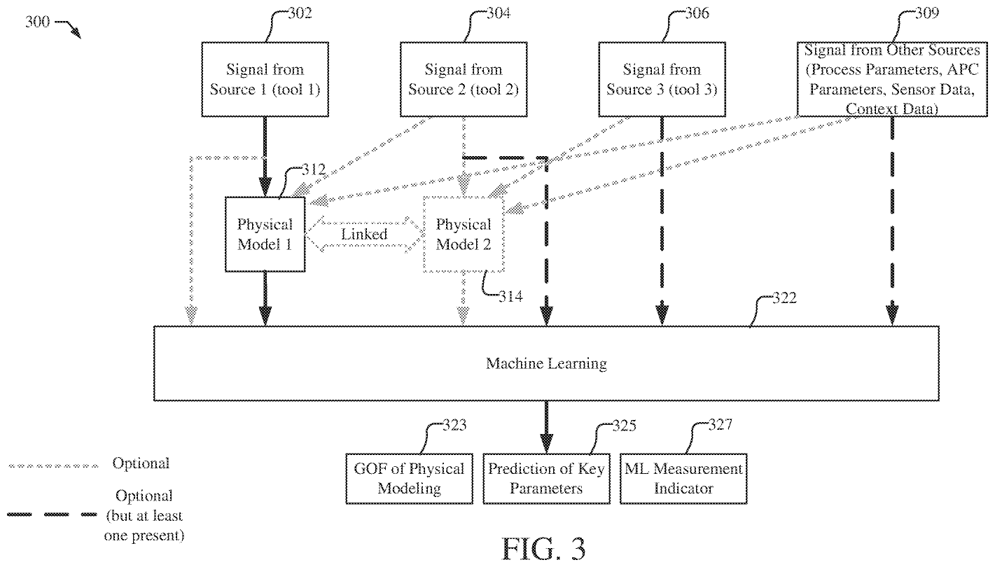

FIG. 3, by way of example, illustrates a workflow 300 for inline measurement, e.g., for characterizing a sample based on one or more physical models and one or more machine learning models, in accordance with the first example scenario with signals collected from multiple data sources, e.g., different tools and/or sources. The one or more physical models and one or more machine learning models, for example, may be generated as discussed in reference to FIG. 2. In FIG. 3, solid black arrows indicate processes that are used in the workflow 300, dashed black arrows indicate processes that are optional, but at least one is present, while dotted grey arrows indicate processes that are optional.

As illustrated, measured signals 302 from the sample are collected from a first data source or tool (Source 1). The measured signals 302 may be collected from any desired metrology device, such as metrology tool 101 shown in FIG. 1, or from any other desired type of metrology device, and may be collected from the same metrology device or same type of metrology device as used for Source 1 in FIG. 2.

Additionally, data is acquired from one or more additional data sources. For example, in some implementations, measured signals 304 and 306 may be collected from one or more additional sources or tools, e.g., illustrated as a second source or tool (Source 2) and a third source or tool (Source 3). The additional measured signals 304, for example, may be collected from a metrology device that is different than Source 1, such as metrology tool 170 shown in FIG. 1, or from any other desired type of metrology device, and may be collected from the same metrology device or same type of metrology device as used for Source 2 in FIG. 2. The measured signals 306 may be collected from a metrology device that is different than Source 1 and Source 2, such as a different type of measurement from either of metrology tools 101 or 170 or from any other desired type of metrology device and may be collected from the same metrology device or same type of metrology device as used for Source 3 in FIG. 2. Further, in some implementations, additional data signals 309, for example, that may be related to the sources (e.g., Source 1, Source 2, and Source 3), may be obtained, such as process parameters, APC parameters, context data; and sensor data from production equipment.

The signals and data from the multiple data sources may be used to extract measurement results from one or more physical models. For example, as illustrated with the solid black arrows, the measured signals 302 from the first source (Source 1) may be used to extract measurement results for the sample from a first physical model 312, which may be the same as the first physical model 212 in FIG. 2. In some implementations, additional data may be used to assist in extracting measurement results from the first physical model 312. For example, as illustrated with the dotted grey arrow, the measured signals 304 from the second source (Source 2) may be used to assist in the extraction of measurement results from the first physical model 312 of the sample. Additionally, as illustrated with the dotted grey arrow, additional data signals 309 may be used to assist in extracting measurement results for the sample from the first physical model 312.

In some implementations, multiple physical models may be used to extract measurement results for the sample. For example, as illustrated with the grey dotted arrows and grey dotted box, a second physical model 314 may be used to extract measurement results for the sample based on measured signals 304 from the second source (Source 2). The second physical model 314, for example, may be the same as the second physical model 214 in FIG. 2. In some implementations, additional data may be used to assist in extracting measurement results from the second physical model 314. For example, as illustrated with the dotted grey arrow, the measured signals 306 from the third source (Source 3) may be used to assist in extracting measurement results for the sample from the second physical model 314. Additionally, as illustrated with the dotted grey arrow, additional data signals 309 may be used to assist in extracting measurement results for the sample from the second physical model 314. Moreover, the multiple physical models may be optimized independently or co-optimized. For example, in some implementations, as illustrated with dotted grey lines, the first physical model 312 and the second physical model 314 may be linked so that at least some parameters may be coupled across the physical models 312 and 314 and the combined parameter space may be searched to fit the measured signals from one or multiple data sources. The first physical model 312, and optionally, the second physical model 314, may be configured to provide goodness of fit 323 of the physical modeling.

One or more trained machine learning models 322 is used to, based on the multiple data sources, predict parameters of interest 325. A machine learning measurement indicator 327 and goodness of fit 323 from the physical modeling may be reported to indicate the measurement quality of the synergized recipe from physical modeling and machine learning. The trained machine learning model 322, for example, may be the same as the machine learning model 222 of FIG. 2 after it has been trained. As illustrated with the solid black arrow, the trained machine learning model 322 uses the measurement results extracted by the first physical model 312 as input features. As indicated with the dashed black arrows, the trained machine learning model 322 may further use input features including at least one of measured signals 304 from the sample collected from the second source (Source 2), measured signals 306 from the sample collected from the third source (Source 3), additional data signals 309, the measurement results extracted by the second physical model 314 based on the additional signals 304 and/or 306, and optionally additional data signals 309, or any combination thereof. In some implementations, as illustrated with the dotted grey arrow, the trained machine learning model 322 optionally may further use input features including the measured signals 302 from the sample collected from the first source (Source 1). In some implementations, the machine learning input features from the measured signals 302 may include data from measured signals, such as at least one data channel or at least one data chunk, that are not used in extracting measurement results from the first physical model 312, as discussed in reference to FIG. 2.

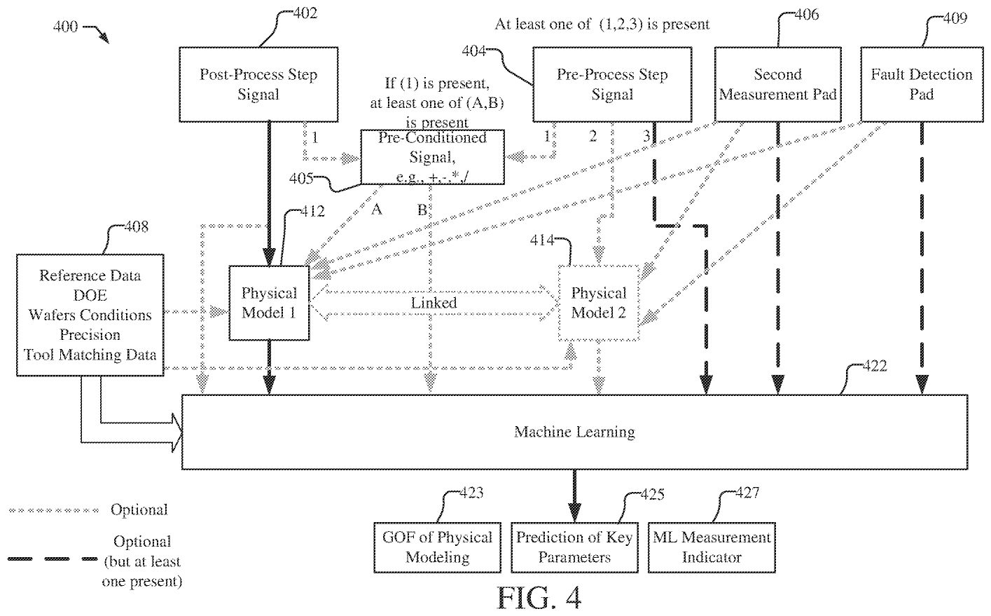

FIG. 4, by way of example, illustrates a workflow 400 for offline recipe creation, e.g., generating one or more physical models and one or more machine learning models, in accordance with a second example scenario with signals collected from multiple data sources, e.g., different manufacturing process steps. In FIG. 4, solid black arrows indicate processes that are used in the workflow 400, dashed black arrows indicate processes that are optional, but at least one is present, while dotted grey arrows indicate processes that are optional.

As illustrated, post-process step measured signals 402 from one or more reference samples are measured from a metrology device. The reference samples, for example, may be OCD target pads or semiconductor devices, and the post-process step measured signals 402 are obtained after a desired step of fabrication of the sample is completed. The post-process step measured signals 402 may be collected from any desired metrology device, such as metrology tool 101 shown in FIG. 1, or from any other desired type of metrology device.

Additionally, pre-process step measured signals 404 from the one or more reference samples are measured using a metrology device, e.g., the same or a different metrology device used for acquiring the post-process step measured signals 402, and used to generate pre-process step data. The pre-process step measured signals 404, for example, are obtained prior to a desired step of fabrication of the sample is completed. In some implementations, the post-process step measured signals 402 and pre-process step measured signals 404 may be combined (e.g., combined by addition, subtraction, multiplication, or division) to form pre-conditioned signals 405. Additionally, data 408 related to the reference samples may be collected, such as reference data for the sample, the design of experiment (DOE). In some implementations, the additional data 408 related to the reference samples may further include wafer conditions, precision, tool matching data, etc. Additionally, data may be obtained from other sources, such as from a second measurement pad 406, from a fault detection pad 409, or any combination thereof. While the first example scenario in FIGS. 2 and 3 emphasized multiple data sources collected from different metrology devices, the second example scenario, for example, illustrates that multiple data sources may come from different measurement pads, or same pad at different process steps. The different measurement pads may be measured from the same or different metrology devices. The pre-process step measured signals 404 and the post-process step measured signals 402 may be measured either on designed OCD targets or devices. The second measurement pad 406, for example, refers to pre-process step measurements and/or post-process step measurements from a measurement pad that is not measured for the pre-process step measured signals 404 and the post-process step measured signals 402. If the pre-process step measured signals 404 and the post-process step measured signals 402 are measured on OCD targets, for example, the second measurement pad 406 may refer to auxiliary signals from device pads, or vice versa.

The signals and data from the multiple data sources may be used to generate one or more physical models. For example, as illustrated with the solid black arrow, the post-process step measured signals 402 from the metrology device may be used to generate a post-process physical model 412 of the sample. In some implementations, additional data may be used to assist in generating the post-process physical model 412. For example, as illustrated with the dotted grey arrow, additional data 408, such as the reference data and/or DOE, and optionally the wafer conditions, precision, and tool matching data, may also be used to assist in the generation of the post-process physical model 412. In another example, as illustrated with the dotted grey arrow, the pre-conditioned signals 405 may be used to assist in the generation of the post-process physical model 412 of the sample. In another example, as illustrated with the dotted grey arrow, signals from the second measurement pad 406 may be used to assist in the generation of the post-process physical model 412 of the sample. In another example, as illustrated with the dotted grey arrow, signals from the fault detection pad 409 may be used to assist in the generation of the post-process physical model 412 of the sample. In some implementations, all or any combination of data 408, and signals from a different measurement pad, e.g., second measurement pad 406 and/or fault detection pad 409, may be used to assist in the generation of the post-process physical model 412.

In some implementations, multiple physical models may be generated. For example, as illustrated with the grey dotted arrows and grey dotted box, a pre-process physical model 414, may be generated based on pre-process step measured signals 404 from the metrology device. In some implementations, additional data may be used to generate the pre-process physical model 414. For example, as illustrated by the dotted grey arrow, additional data 408, such as the reference data and/or DOE, and optionally the wafer conditions, precision, and tool matching data, may also be used to assist in the generation of the pre-process physical model 414. In another example, as illustrated with the dotted grey arrow, signals from the second measurement pad 406 may be used to assist in the generation of the pre-process physical model 414 of the sample. In another example, as illustrated with the dotted grey arrow, signals from the fault detection pad 409 may be used to assist in the generation of the pre-process physical model 414 of the sample. In some implementations, all or any combination of data 408, and signals from the second measurement pad 406 and fault detection pad 409 may be used to assist in the generation of the pre-process physical model 414. Moreover, the multiple physical models may be optimized independently or co-optimized. For example, in some implementations, as illustrated with dotted grey lines, the post-process physical model 412 and the pre-process physical model 414 may be linked so that at least some parameters may be coupled across the post-process physical model 412 and the pre-process physical model 414 and the combined parameter space may be searched to fit the measured signals from one or multiple data sources. The post-process physical model 412, and optionally, the pre-process physical model 414, may be configured to provide goodness of fit 423 of the physical modeling.

One or more machine learning models 422 is built and trained using the multiple data sources to predict parameters of interest 425. A machine learning measurement indicator 427 may be developed and reported together with the goodness of fit 423 from the physical modeling to indicate the measurement quality of the recipe synergized from physical modeling and machine learning. As illustrated with the solid black arrows, the machine learning model 422 is built using the post-process measurement results extracted by the post-process physical model 412 as input features. As indicated by the dashed black arrows, the input features of machine learning model 422 additionally includes the pre-process step data that is produced based on the pre-process step measured signals 404. The pre-process step data may be produced based on the pre-process step measured signals 404 in multiple ways. For example, as illustrated in FIG. 4, pre-process step data may be produced in three different ways from the pre-process step measured signals 404, labeled 1, 2, and 3, where at least one of (1), (2), or (3), or any combination thereof, is used. As illustrated with label 1 for the pre-process step measured signals 404, the pre-process step data may be generated by combining the pre-process step measured signals 404 with the post-process step measured signals 402 to form pre-conditioned signals 405. As described in FIG. 4, in some implementations, if the pre-conditioned signals 405 are generated, the pre-conditioned signals 405 may be (A) provided to the post-process physical model 412 and the machine learning model 422 is built based at least in part on the post-process measurement results extracted by the post-process physical model 412, or (B) the pre-conditioned signals 405 are provided to the machine learning model 422 and the machine learning model 422 is built based at least in part on the pre-conditioned signals 405. Additionally, as further described in FIG. 4, in some implementations, at least one of (A) or (B) may be used with workflow 400. As illustrated with label 2 for the pre-process step measured signals 404, the pre-process step data may be generated by providing the pre-process step measured signals 404 to the pre-process physical model 414, and the machine learning model 422 is built based at least in part on the pre-process measurement results extracted by the pre-process physical model 414. As illustrated with label 3 for the pre-process step measured signals 404, the pre-process step data may be generated by providing the pre-process step measured signals 404 to the machine learning model 422, and the machine learning model 422 is built based at least in part on the pre-process step measured signals 404.

Additionally, as indicated with the dashed black arrows, the machine learning model 422 is built using additional data including at least one of pre-process step data (i.e., at least one of (1), (2), or (3) for the pre-process step measured signals 404, or any combination thereof), signals from the second measurement pad 406, and signals from the fault detection pad 409, or any combination thereof. In some implementations, as illustrated with the dotted grey arrows, the machine learning model 422 optionally may be built further using the post-process step measured signals 402, the pre-conditioned signal 405, the measurement results extracted by the pre-process physical model 414, or some combination thereof.

The machine learning model 422 is trained with at least a portion of the data 408, such as the reference data and/or DOE, and optionally the wafer conditions, precision, and tool matching data.

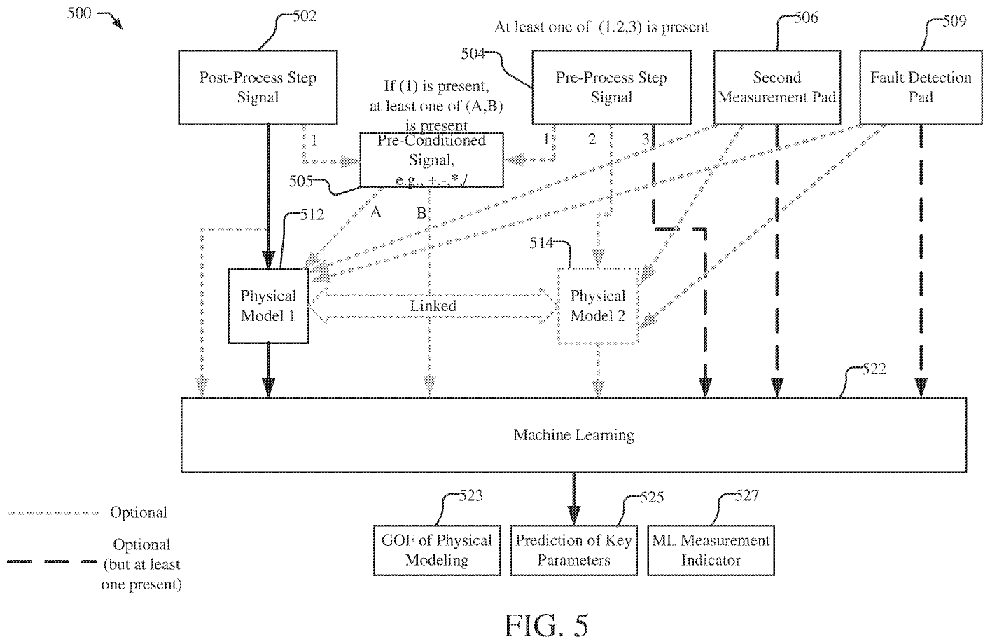

FIG. 5, by way of example, illustrates a workflow 500 for inline measurement, e.g., for characterizing a sample based on one or more physical models and one or more machine learning models, in accordance with the second example scenario with signals collected from multiple data sources, e.g., different manufacturing process steps. The one or more physical models and one or more machine learning models, for example, may be generated as discussed in reference to FIG. 4. In FIG. 5, solid black arrows indicate processes that are used in the workflow 500, dashed black arrows indicate processes that are optional, but at least one is present, while dotted grey arrows indicate processes that are optional.

As illustrated, post-process step measured signals 502 from the sample are collected from a metrology device. The sample, for example, may be an OCD target pad or a semiconductor device, and the post-process step measured signals 502 are obtained after a desired step of fabrication of the sample is completed. The post-process step measured signals 502 may be collected from any desired metrology device, such as metrology tool 101 shown in FIG. 1, or from any other desired type of metrology device, and may be collected from the same metrology device or same type of metrology device as used to acquire the post-process step measured signals 402 in FIG. 4.

Additionally, pre-process step measured signals 504 from the sample are collected using a metrology device, e.g., the same or a different metrology device used for acquiring the post-process step measured signals 502, and the same metrology device or same type of metrology device as used to acquire the pre-process step measured signals 404 in FIG. 4. The pre-process step measured signals 504 are used to generate pre-process step data. The pre-process step measured signals 504, for example, are obtained prior to a desired step of fabrication of the sample is completed. In some implementations, the post-process step measured signals 502 and pre-process step measured signals 504 may be combined (e.g., combined by addition, subtraction, multiplication, or division) to form pre-conditioned signals 505. Additionally, data may be obtained from other sources, such as from a second measurement pad 506, from a fault detection pad 509, or any combination thereof. The pre-process step measured signals 504 and the post-process step measured signals 502 may be measured either on designed OCD targets or devices. The second measurement pad 506, for example, refers to pre-process step measurements and/or post-process step measurements from a measurement pad that is not measured for the pre-process step measured signals 504 and the post-process step measured signals 502. If the pre-process step measured signals 504 and the post-process step measured signals 502 are measured on OCD targets, for example, the second measurement pad 506 may refer to auxiliary signals from device pads, or vice versa.

The signals and data from the multiple data sources may be used to extract measurement results from one or more physical models. For example, as illustrated with the solid black arrows, the post-process step measured signals 502 may be used to extract measurement results for the sample from a post-process physical model 512, which may be the same as the post-process physical model 412 in FIG. 4. In some implementations, additional data may be used to assist in extracting measurement results from the post-process physical model 512. For example, as illustrated with the dotted grey arrow, the pre-conditioned signals 505 may be used to assist in the extraction of measurement results from the post-process physical model 512 of the sample. In another example, as illustrated with the dotted grey arrow, signals from the second measurement pad 506 may be used to assist in the extraction of measurement results from the post-process physical model 512 of the sample. In another example, as illustrated with the dotted grey arrow, signals from the fault detection pad 509 may be used to assist in the extraction of measurement results from the post-process physical model 512 of the sample. In some implementations, all or any combination of signals from second pad 506 and fault detection pad 509 may be used to assist in the extraction of measurement results from the post-process physical model 512 of the sample.

In some implementations, multiple physical models may be used to extract measurement results for the sample. For example, as illustrated with the grey dotted arrows and grey dotted box, a pre-process physical model 514 may be used to extract measurement results for the sample based on pre-process step measured signals 504. The pre-process physical model 514 may be the same as the pre-process physical model 414 in FIG. 4. In some implementations, additional data may be used to assist in extracting measurement results from the pre-process physical model 514. For example, as illustrated with the dotted grey arrow, signals from the second measurement pad 506 may be used to assist in the extraction of measurement results from the pre-process physical model 514 of the sample. In another example, as illustrated with the dotted grey arrow, signals from the fault detection pad 509 may be used to assist in the extraction of measurement results from the pre-process physical model 514 of the sample. In some implementations, all or any combination of signals from second pad 506 and fault detection pad 509 may be used to assist in the extraction of measurement results from the pre-process physical model 514 of the sample. Moreover, multiple physical models may be optimized independently or co-optimized. For example, in some implementations, as illustrated with dotted grey lines, the post-process physical model 512 and the pre-process physical model 514 may be linked so that at least some parameters may be coupled across the post-process physical model 512 and the pre-process physical model 514 and the combined parameter space may be searched to fit the measured signals from one or multiple data sources. The post-process physical model 512, and optionally, the pre-process physical model 514, may be configured to provide goodness of fit 523 of the physical modeling.

One or more trained machine learning models 522 is used, based on the multiple data sources, to predict parameters of interest 525. A machine learning measurement indicator 527 may be developed and reported together with the goodness of fit 523 from the physical modeling to indicate the measurement quality of the recipe synergized from physical modeling and machine learning. As illustrated with the solid black arrows, the trained machine learning model 522 uses the post-process measurement results extracted by the post-process physical model 512 as input data, as well as the pre-process step data that is produced based on the pre-process step measured signals 504.

The pre-process step data may be produced based on the pre-process step measured signals 504 in multiple ways. For example, as illustrated in FIG. 5, pre-process step data may be produced in three different ways from the pre-process step measured signals 504, labeled 1, 2, and 3, where at least one of (1), (2), or (3), or any combination thereof, is used. As illustrated with label 1 for the pre-process step measured signals 504, the pre-process step data may be generated by combining the pre-process step measured signals 504 with the post-process step measured signals 502 to form pre-conditioned signals 505. As described in FIG. 5, in some implementations, if the pre-conditioned signals 505 are generated, the pre-conditioned signals 505 may be (A) provided to the post-process physical model 512 and the trained machine learning model 522 receives input data in the form of post-process measurement results extracted by the post-process physical model 512, or (B) the pre-conditioned signals 505 are provided to the trained machine learning model 522 as input data. Additionally, as further described in FIG. 5, in some implementations, at least one of (A) or (B) may be used with workflow 500. As illustrated with label 2 for the pre-process step measured signals 504, the pre-process step data may be generated by providing the pre-process step measured signals 504 to the pre-process physical model 514, and the trained machine learning model 522 uses the measurement results extracted by the pre-process physical model 514 as input data. As illustrated with label 3 for the pre-process step measured signals 504, the pre-process step data may be generated by providing the pre-process step measured signals 504 to the trained machine learning model 522 as input data.

In some implementations, as illustrated with the dotted grey arrows, the trained machine learning model 522 optionally may further use input data including the post-process step measured signals 502.

In some implementations, the primary data, e.g., the measured signals used in the physical modeling and in some implementations, the machine learning models, and auxiliary data, e.g., supplementary data used in the machine learning models and in some implementations, the physical modeling, may originate from different tool sets, or may originate from same tool set, but different data channels, or may originate from the same tool set and same data channel but from different wavelength ranges, time spans, etc. Different data sources may collect data from the same sample sites, e.g., OCD target or on device, of the same wafer, from the same process step, or from different process steps. Different data sources may collect data from different sample sites of the same wafer from the same or different process steps, e.g., when underlying structures have correlated parameters, so that analyzing the combined data may improve the overall performance. As illustrated, at least one physical model may be created to analyze measured signals from at least one data source. Moreover, if more than one physical model is used, the multiple physical models may be optimized independently or co-optimized, e.g., the physical models may be linked so that at least some parameters may be coupled across the physical models and the combined parameter space may be searched to fit the measured signals from one or multiple data sources. The primary data and the auxiliary data may have different natures, e.g., some of the data may be metrology data collected from a tool set, while other data may be sensor data from process equipment, or wafer process parameters such as gas flow rate, APC parameters, or context data, such a specific process tool. Additionally, feature engineering and signal preprocessing may be applied before data from all sources are provided to the machine learning model for training and prediction. The machine learning algorithms, for example, may include, but are not limited to, linear regression, neural networks, deep learning, convolution neural-network (CNN), ensemble methods, support vector machine (SVM), random forest, etc., or combination of multiple models in sequential mode and/or parallel mode.

The illustrated workflows efficiently combine various measurement techniques and the use of multiple data source through synergizing physical modeling and machine learning to produce more usable information than is provided by an individual measurement technique or single data source. The physical modeling may be performed with desired measurement devices using previously well-established modeling solutions and the physical modeling results may be combined with other hard or impossible to model data, which may be referred as auxiliary data, for machine learning training and prediction. The resulting process thus provides viable solutions with advantages of both physical modeling and machine learning, while controlling the computation cost, enabling acceptable TTS for production, and is easily implemented and used in practice. Additionally, predictive power may be increased through the use of data, such as process parameters and sensor data from production equipment, which is combined with metrology data through data mining and data fusion as discussed herein. The proposed methods are flexible to accommodate a variety of signals of different nature, while at the same time maximizing usage of existing well-developed algorithms for each type of data source. Moreover, the approach discussed herein has universal application and, for example, may be applied to measurements of any devices, OCD or thin film or other types of targets.

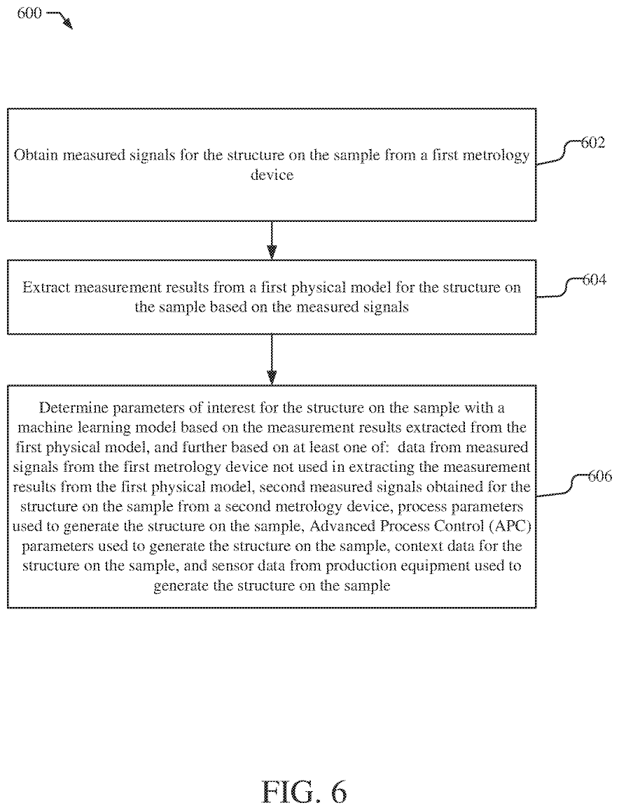

FIG. 6 shows an illustrative flowchart depicting an example method 600 for characterizing a structure on a sample, according to some implementations. In some implementations, the example method 600 may be performed by at least one memory, such as memory 164, that is configured to store measured signals, measurement results, one or more physical models, one or more machine learning models, and parameters of interest for the structure and that is coupled to one or more processors, e.g., such as processor 162 in computing system 160 in FIG. 1, implementing the workflow 300 illustrated in FIG. 3.

The one or more processors may obtain measured signals for the structure on the sample from a first metrology device (602). For example, measured signals for the structure on the sample may be obtained by the metrology device 100 shown in FIG. 1. The measured signals for the structure on the sample, for example, may be the measured signals 302 shown in FIG. 3. A means for obtaining measured signals for the structure on the sample from a first metrology device may be, e.g., metrology device 100 shown in FIG. 1 and the at least one memory 164 and at least one processor 162 in the computing system 160 shown in FIG. 1.

The one or more processors may extract measurement results from a first physical model for the structure on the sample based on the measured signals (604). For example, the first physical model may be the first physical model 312 shown in FIG. 3. A means for extracting measurement results from a first physical model for the structure on the sample based on the measured signals may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

The one or more processors may determine parameters of interest for the structure on the sample with a machine learning model based on the measurement results extracted from the first physical model, and further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample (606). The machine learning model, for example, may be trained machine learning model 322 that receives measurement results extracted from the first physical model 312 in FIG. 3. Additionally, second measured signals obtained for the structure on the sample from a second metrology device may be measured signals 304, and the process parameters used to generate the structure on the sample, APC parameters used to generate the structure on the sample, context data for the structure on the sample, and sensor data from production equipment used to generate the structure on the sample may be the additional data signals 309 shown in FIG. 3. A means for determining parameters of interest for the structure on the sample with a machine learning model based on the measurement results extracted from the first physical model, and further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample may be, e.g., the at least one processor 162 configured to implement one or more physical models, e.g., based on instructions for Model 164ml from the computer-readable program code 166 on non-transitory computer-usable storage medium, such as memory 164 shown in FIG. 1.

In some implementations, the data from measured signals may be one of at least one data channel, which may be a measurement subsystem defined by at least one of the energy source, such as the light source, the optical path directed by optical parts, the detector, or a combination thereof, and at least one data chunk, which may be, e.g., a subset of wavelengths, frequencies, angles, time span, or any combination of the above from a full data set provided by the at least one data channel, e.g., as discussed in reference to data provided to the machine learning model 322 from measured signals 302 in FIG. 3.

In some implementations, the machine learning model may be generated based on measurement results extracted by the first physical model for one or more reference samples for the structure and at least one of reference data and design of experiment information, e.g., as illustrated by the black arrow from the first physical model 212 and the block arrow from the additional data 208 to the machine learning model 222 in FIG. 2. The machine learning model may be generated based further on at least one of: data from measured signals not used in generating the first physical model, second measured signals obtained for the one or more reference samples from the second metrology device, process parameters used to generate the one or more reference samples, APC parameters used to generate the one or more reference samples, context data for the one or more reference samples, and sensor data from production equipment used to generate the one or more reference samples, as illustrated by the black dashed lines from the measured signals 204 and additional data signals 209 to the machine learning model 222 in FIG. 2.

In some implementations, the measurement results may be extracted from the first physical model for the structure on the sample further based on the second measured signals for the structure on the sample from the second metrology device, e.g., as illustrated by the grey dotted line from measured signals 304 to the first physical model 312 shown in FIG. 3.

In some implementations, the first measurement results may be extracted from the first physical model for the structure on the sample further based on at least one of the process parameters, the APC parameters, the context data, and the sensor data from production equipment, e.g., as illustrated by grey dotted line from additional data signals 309 to the first physical model 312 in FIG. 3.

In some implementations, the one or more processors may further extract second measurement results from a second physical model for the structure on the sample based on the second measured signals from the second metrology device and the machine learning model determines the parameters of interest for the structure on the sample further based on the second measurement results extracted from the second physical model, e.g., as illustrated by second physical model 314, and the grey dotted line from measured signals 304 to the second physical model 314, and the grey dotted line from the second physical model 314 to the trained machine learning model 322 in FIG. 3. By way of example, in some implementations, the second measurement results are extracted from the second physical model for the structure on the sample further based on third measured signals for the structure on the sample from a third metrology device, e.g., as illustrated by grey dotted line from measured signals 306 to the second physical model 314 in FIG. 3. By way of example, in some implementations, the second measurement results may be extracted from the second physical model for the structure on the sample further based on at least one of the process parameters, the APC parameters, the context data, and the sensor data from production equipment, e.g., as illustrated by black dashed line from additional data signals 309 to the second physical model 314 in FIG. 3. A means for extracting second measurement results from a second physical model for the structure on the sample based on the second measured signals from the second metrology device, wherein the machine learning model determines the parameters of interest for the structure on the sample further based on the second measurement results extracted from the second physical model may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

In some implementations, the machine learning model determines the parameters of interest for the structure on the sample further based on the second measured signals from the second metrology device and further based on third measured signals for the structure on the sample from a third metrology device, e.g., as illustrated by black dashed line from measured signals 304 and the measured signals 306 to the trained machine learning model 322 in FIG. 3.

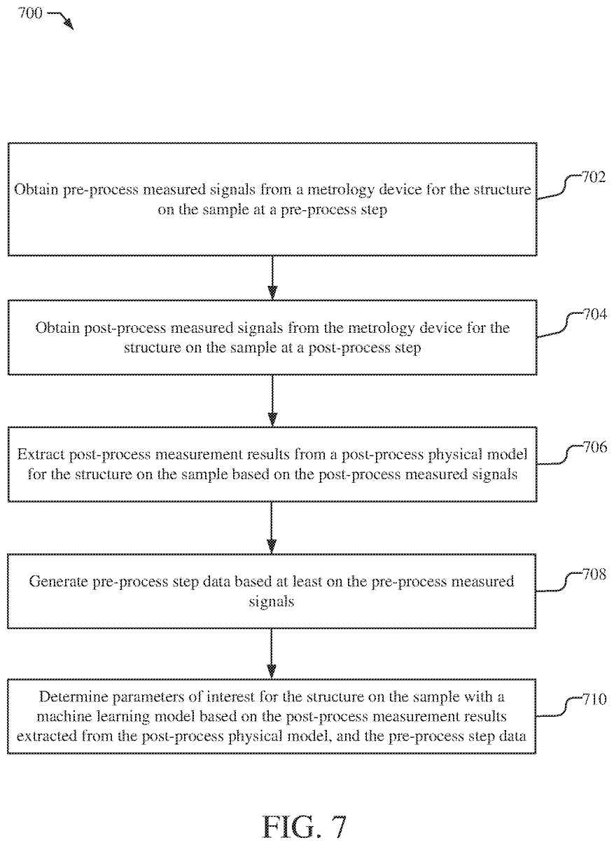

FIG. 7 shows an illustrative flowchart depicting an example method 700 for characterizing a structure on a sample, according to some implementations. In some implementations, the example method 700 may be performed by at least one memory, such as memory 164, that is configured to store measured signals, measurement results, one or more physical models, one or more machine learning models, and parameters of interest for the structure and that is coupled to one or more processors, e.g., such as processor 162 in computing system 160 in FIG. 1, implementing the workflow 500 illustrated in FIG. 5.

The one or more processors may obtain pre-process step metrology signals from a metrology device for the structure on the sample at a pre-process step (702). For example, the pre-process step measured signals may be obtained by the metrology device 100 shown in FIG. 1. The pre-process step measured signals, for example, may be the pre-process step measured signals 504 shown in FIG. 5. A means for obtaining pre-process step metrology signals from a metrology device for the structure on the sample at a pre-process step may be, e.g., metrology device 100 shown in FIG. 1 and the at least one memory 164 and at least one processor 162 in the computing system 160 shown in FIG. 1.

The one or more processors may obtain post-process step measured signals from the metrology device for the structure on the sample at a post-process step (704). For example, the post-process step measured signals may be obtained by the metrology device 100 shown in FIG. 1. The post-process step measured signals for the structure on the sample, for example, may be the post-process step measured signals 502 shown in FIG. 5. A means for obtaining post-process step measured signals from the metrology device for the structure on the sample at a post-process step may be, e.g., metrology device 100 shown in FIG. 1 and the at least one memory 164 and at least one processor 162 in the computing system 160 shown in FIG. 1.

The one or more processors may extract post-process measurement results from a post-process physical model for the sample based on the post-process step measured signals (706). For example, the post-process physical model may be the post-process physical model 512 shown in FIG. 5. A means for extracting post-process measurement results from a post-process physical model for the sample based on the post-process step measured signals may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

The one or more processors may generate pre-process step data based at least on the pre-process step measured signals (708). For example, the pre-process step data generated based at least on the pre-process step measured signals may be any of the labels 1, 2, and 3 from pre-process step measured signals 504 shown in FIG. 5. A means for generating pre-process step data based at least on the pre-process step measured signals may be, e.g., metrology device 100 shown in FIG. 1 and the at least one memory 164 and at least one processor 162 in the computing system 160 shown in FIG. 1.

The one or more processors may determine parameters of interest for the sample with a machine learning model based on the post-process measurement results extracted from the post-process physical model, and the pre-process step data (710). The trained machine learning model, for example, may be the trained machine learning model 522 that receives the post-process measurement results extracted by the post-process physical model 512, and the pre-process step data, e.g., any of the labels 1, 2, and 3 from pre-process step measured signals 504 shown in FIG. 5. A means for determining parameters of interest for the sample with a machine learning model based on the post-process measurement results extracted from the post-process physical model, and the pre-process step data may be, e.g., the at least one processor 162 configured to implement one or more physical models, e.g., based on instructions for Model 164ml from the computer-readable program code 166 on non-transitory computer-usable storage medium, such as memory 164 shown in FIG. 1.

In some implementations, the machine learning model may determine the parameters of interest for the structure on the sample further based on at least one of the pre-process step measured signals, second measured signals obtained from a measurement pad and third measured signals obtained from a fault detection pad, e.g., as illustrated by the black dashed arrows from the pre-process step measured signals 504, signals from second measurement pad 506, and from the fault detection pad 509 to the machine learning model 522 shown in FIG. 5. The pre-process step measured signals, second measured signals obtained from a measurement pad and third measured signals obtained from a fault detection pad may originate from different measurement pads, or from the same pad at different process steps, and can be measured from the same or different metrology devices.

In some implementations, the post-process measurement results are extracted from the post-process physical model further based on at least one of the second measured signals from the measurement pad and the third measured signals from the fault detection pad, e.g., as illustrated by the grey dotted arrows from the second measurement pad 506 and the fault detection pad 509 to the post-process physical model 512.

In some implementations, the pre-process step data may include a pre-conditioned signal generated based on a combination of the pre-process step measured signals and the post-process step measured signals, e.g., as illustrated by the pre-conditioned signals 505 and the grey dotted line from the pre-conditioned signals 505 to the machine learning model 522 shown in FIG. 5.

In some implementations, the one or more processors may further generate a pre-conditioned signal based on a combination of the pre-process step measured signals and the post-process step measured signals, where the post-process measurement results is extracted from the post-process physical model further based on the pre-conditioned signal, e.g., as illustrated by the pre-conditioned signals 505 and the grey dotted line from the pre-conditioned signals 505 to the post-process physical model 512 shown in FIG. 5. A means for generating a pre-conditioned signal based on a combination of the pre-process step measured signals and the post-process step measured signals, where the post-process measurement results is extracted from the post-process physical model further based on the pre-conditioned signal may be, e.g., metrology device 100 shown in FIG. 1 and the at least one memory 164 and at least one processor 162 in the computing system 160 shown in FIG. 1.

In some implementations, the one or more processors may further extract pre-process measurement results from a pre-process physical model based on the pre-process step measured signals, where the pre-process step data includes the pre-process measurement results extracted from the pre-process physical model, e.g. as illustrated by the pre-process physical model 514 and the grey dotted line from the pre-process step measured signals 504 to the pre-process physical model 514 and the grey dotted line from the pre-process physical model 514 to the machine learning model 522 shown in FIG. 5. A means for extracting pre-process measurement results from a pre-process physical model based on the pre-process step measured signals, where the pre-process step data includes the pre-process measurement results extracted from the pre-process physical model may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

By way of example, in some implementations, the pre-process measurement results are extracted from the pre-process physical model further based on at least one of second measured signals obtained from a measurement pad and third measured signals obtained from a fault detection pad, e.g., as illustrated by the grey dotted line from the second measurement pad 506 to the pre-process physical model 514 and the grey dotted line from the fault detection pad 509 to the pre-process physical model 514 shown in FIG. 5.

In some implementations, the pre-process step data may include the pre-process step measured signals, e.g., as illustrated by the black dashed line from the pre-process step measured signals 504 to the machine learning model 522 shown in FIG. 5.

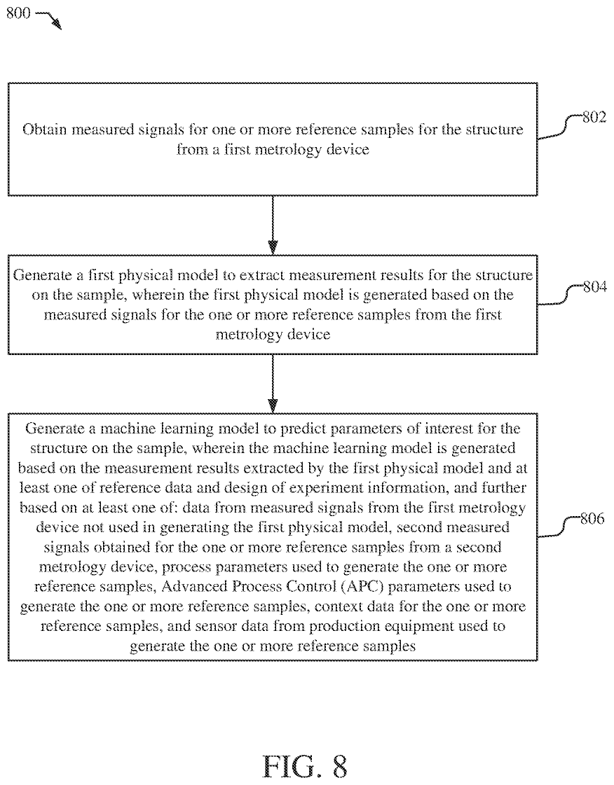

FIG. 8 shows an illustrative flowchart depicting an example method 800 for characterizing a structure on a sample, according to some implementations. In some implementations, the example method 800 may be performed by at least one memory, such as memory 164, that is configured to store measured signals, measurement results, one or more physical models, one or more machine learning models, and parameters of interest for the structure and that is coupled to one or more processors, e.g., such as processor 162 in computing system 160 in FIG. 1, implementing the workflow 200 illustrated in FIG. 2.

The one or more processors may obtain measured signals for one or more reference samples for the structure from a first metrology device (802). For example, measured signals for one or more reference samples may be obtained by the metrology device 100 shown in FIG. 1. The measured signals for one or more reference samples, for example, may be the measured signals 202 shown in FIG. 2. A means for obtaining measured signals for one or more reference samples for the structure from a first metrology device may be, e.g., metrology device 100 shown in FIG. 1 and the at least one memory 164 and at least one processor 162 in the computing system 160 shown in FIG. 1.

The one or more processors may generate a first physical model to extract measurement results for the structure on the sample, where the first physical model is generated based on the measured signals for the one or more reference samples from the first metrology device (804). For example, the first physical model generated based on the measured signals for the one or more reference samples from the first metrology device may be the first physical model 212 shown in FIG. 2. A means for generating a first physical model to extract measurement results for the structure on the sample, where the first physical model is generated based on the measured signals for the one or more reference samples from the first metrology device may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

The one or more processors may generate a machine learning model to predict parameters of interest for the structure on the sample, where the machine learning model is generated based on the measurement results extracted by the first physical model and at least one of reference data and design of experiment information, and further based on at least one of: data from measured signals from the first metrology device not used in generating the first physical model, second measured signals obtained for the one or more reference samples from a second metrology device, process parameters used to generate the one or more reference samples, Advanced Process Control (APC) parameters used to generate the one or more reference samples, context data for the one or more reference samples, and sensor data from production equipment used to generate the one or more reference samples (806). The machine learning model to predict parameters of interest for the structure on the sample, for example, may be machine learning model 222 that is generated based on the measurement results extracted by the first physical model 212 and at least one of reference data and design of experiment information in additional data 208 shown in FIG. 2. Additionally, the data from measured signals may be at least one data channel or at least one data chunk from the first metrology device that is not used by the first physical model 212, second measured signals obtained for the one or more reference samples from a second metrology device may be measured signals 204, and the process parameters used to generate the one or more reference samples, APC parameters used to generate the one or more reference samples, context data for the one or more reference samples, and sensor data from production equipment may be the additional data signals 209 shown in FIG. 2. A means for generating a machine learning model to predict parameters of interest for the structure on the sample, where the machine learning model is generated based on the measurement results extracted by the first physical model and at least one of reference data and design of experiment information, and further based on at least one of: data from measured signals from the first metrology device not used in generating the first physical model, second measured signals obtained for the one or more reference samples from a second metrology device, process parameters used to generate the one or more reference samples, Advanced Process Control (APC) parameters used to generate the one or more reference samples, context data for the one or more reference samples, and sensor data from production equipment used to generate the one or more reference samples may be, e.g., the at least one processor 162 configured to implement one or more physical models, e.g., based on instructions for Model 164ml from the computer-readable program code 166 on non-transitory computer-usable storage medium, such as memory 164 shown in FIG. 1.

In some implementations, the data from measured signals may be one of at least one data channel, which may be a measurement subsystem defined by at least one of the energy source, such as the light source, the optical path directed by optical parts, the detector, or a combination thereof, and at least one data chunk, which may be, e.g., a subset of wavelengths, frequencies, angles, time span, or any combination of the above from a full data set provided by the at least one data channel, e.g., as discussed in reference to data provided to the machine learning model 222 from measured signals 202 in FIG. 2.

In some implementations, the first physical model may be generated further based on the second measured signals for the one or more reference samples from the second metrology device, e.g., as illustrated by the grey dotted line from measured signals 204 to the first physical model 212 shown in FIG. 2.

In some implementations, the first physical model may be generated further based on at least one of the process parameters, the APC parameters, the context data, and the sensor data from production equipment, e.g., as illustrated by the grey dotted line from additional data signals 209 to the first physical model 212 in FIG. 2.

In some implementations, the one or more processors may further generate a second physical model to extract second measurement results for the structure on the sample, where the second physical model is generated based on the second measured signals for the one or more reference samples from the second metrology device, and the machine learning model may be generated further based on the second measurement results extracted by the second physical model, e.g., as illustrated by second physical model 214, and the grey dotted line from measured signals 204 to the second physical model 214, and the grey dotted line from the second physical model 214 to the machine learning model 222 in FIG. 2. By way of example, in some implementations, the second physical model is generated further based on third measured signals for the one or more reference samples from a third metrology device, e.g., as illustrated by grey dotted line from measured signals 206 to the second physical model 214 in FIG. 2. By way of example, in some implementations, the second physical model is generated further based on at least one of the process parameters, the APC parameters, the context data, and the sensor data from production equipment, e.g., as illustrated by the grey dotted line from additional data signals 209 to the second physical model 214 in FIG. 2. A means for generating a second physical model to extract second measurement results for the structure on the sample, where the second physical model is generated based on the second measured signals for the one or more reference samples from the second metrology device, and the machine learning model may be generated further based on the second measurement results extracted by the second physical model may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

In some implementations, the machine learning model may be generated further based on the second measured signals from the second metrology device and further based on third measured signals for the one or more reference samples from a third metrology device, e.g., as illustrated by black dashed lines from measured signals 204 and the measured signals 206 to the machine learning model 222 in FIG. 2.

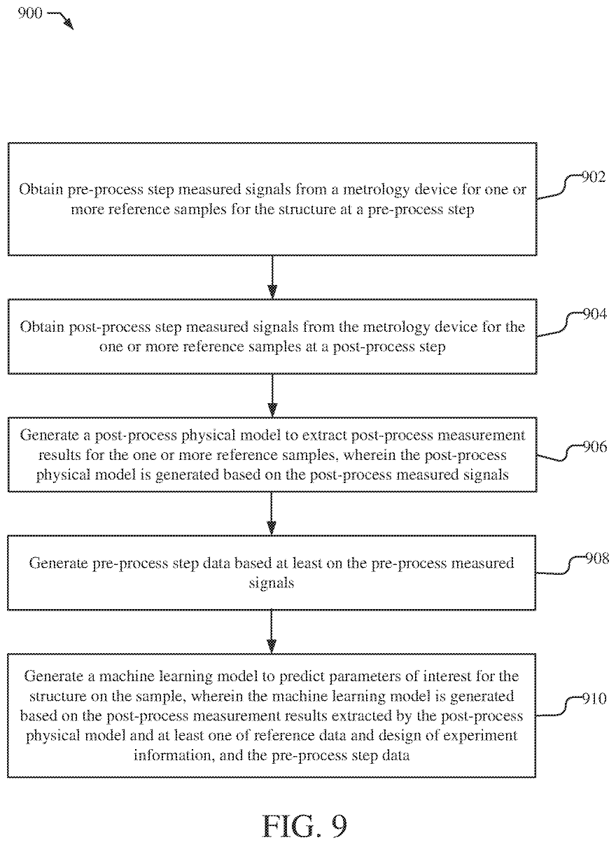

FIG. 9 shows an illustrative flowchart depicting an example method 900 for characterizing a structure on a sample, according to some implementations. In some implementations, the example method 900 may be performed by at least one memory, such as memory 164, that is configured to store measured signals, measurement results, one or more physical models, one or more machine learning models, and parameters of interest for the structure and that is coupled to one or more processors, e.g., such as processor 162 in computing system 160 in FIG. 1, implementing the workflow 400 illustrated in FIG. 4.

The one or more processors may obtain pre-process step measured signals from a metrology device for one or more reference samples for the structure at a pre-process step (902). For example, pre-process step measured signals for one or more reference samples may be obtained by the metrology device 100 shown in FIG. 1. The pre-process step measured signals for one or more reference samples, for example, may be the pre-process step measured signals 404 shown in FIG. 4. A means for obtaining pre-process step measured signals from a metrology device for one or more reference samples for the structure at a pre-process step may be, e.g., metrology device 100 shown in FIG. 1 and the at least one memory 164 and at least one processor 162 in the computing system 160 shown in FIG. 1.

The one or more processors may obtain post-process step measured signals from the metrology device for the one or more reference samples at a post-process step (904). For example, the post-process step measured signals for the one or more reference samples may be obtained by the metrology device 100 shown in FIG. 1. The post-process step measured signals for the one or more reference samples, for example, may be the post-process step measured signals 402 shown in FIG. 4. A means for obtaining post-process step measured signals from the metrology device for the one or more reference samples at a post-process step may be, e.g., metrology device 100 shown in FIG. 1 and the at least one memory 164 and at least one processor 162 in the computing system 160 shown in FIG. 1.

The one or more processors may generate a post-process physical model to extract post-process measurement results for the one or more reference samples, where the post-process physical model is generated based on the post-process step measured signals (906). For example, the post-process physical model generated based on the post-process step measured signals may be the post-process physical model 412 shown in FIG. 4. A means for generating a post-process physical model to extract post-process measurement results for the one or more reference samples, where the post-process physical model is generated based on the post-process step measured signals may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

The one or more processors may generate pre-process step data based at least on the pre-process step measured signals (908). For example, the pre-process step data generated based at least on the pre-process step measured signals may be any of the labels 1, 2, and 3 from pre-process step measured signals 404 shown in FIG. 4. A means for generating pre-process step data based at least on the pre-process step measured signals may be, e.g., metrology device 100 shown in FIG. 1 and the at least one memory 164 and at least one processor 162 in the computing system 160 shown in FIG. 1.

The one or more processors may generate a machine learning model to predict parameters of interest for the structure on the sample, where the machine learning model is generated based on the post-process measurement results extracted by the post-process physical model and at least one of reference data and design of experiment information, and the pre-process step data (910). The machine learning model, for example, may be machine learning model 422 that is generated based on the post-process measurement results extracted by the post-process physical model 412 and at least one of the reference data and design of experiment information in additional data 408 shown in FIG. 4, and the pre-process step data, e.g., any of the labels 1, 2, and 3 from pre-process step measured signals 404 shown in FIG. 4. A means for generating a machine learning model to predict parameters of interest for the structure on the sample, where the machine learning model is generated based on the post-process measurement results extracted by the post-process physical model and at least one of reference data and design of experiment information, and the pre-process step data may be, e.g., the at least one processor 162 configured to implement one or more physical models, e.g., based on instructions for Model 164ml from the computer-readable program code 166 on non-transitory computer-usable storage medium, such as memory 164 shown in FIG. 1.

In some implementations, the machine learning model may be generated further based on at least one of the pre-process step measured signals, second measured signals obtained from a measurement pad, and third measured signals obtained from a fault detection pad, e.g., as illustrated by the black dashed arrows from the pre-process step measured signals 404, from second measurement pad 406, and from the fault detection pad 409 to the machine learning model 422 shown in FIG. 4. The pre-process step measured signals, second measured signals obtained from a measurement pad, and third measured signals obtained from a fault detection pad may originate from different measurement pads, or from the same pad at different process steps, and can be measured from the same or different metrology devices.

In some implementations, the post-process physical model may be generated further based on at least one of the second measured signals from the measurement pad and the third measured signals from the fault detection pad, e.g., as illustrated by the grey dotted arrows from the second measurement pad 406 and the fault detection pad 409 to the post-process physical model 412 shown in FIG. 4.

In some implementations, the pre-process step data may include a pre-conditioned signal generated based on a combination of the pre-process step measured signals and the post-process step measured signals, e.g., as illustrated by the pre-conditioned signals 405 and the grey dotted line from the pre-conditioned signals 405 to the machine learning model 422 shown in FIG. 4.

In some implementations, the one or more processors may further generate a pre-conditioned signal based on a combination of the pre-process step measured signals and the post-process step measured signals, where the post-process physical model is generated further based on the pre-conditioned signal, e.g., as illustrated by the pre-conditioned signals 405 and the grey dotted line from the pre-conditioned signals 405 to the post-process physical model 412 shown in FIG. 4. A means for generating a pre-conditioned signal based on a combination of the pre-process step measured signals and the post-process step measured signals, where the post-process physical model is generated further based on the pre-conditioned signal may be, e.g., metrology device 100 shown in FIG. 1 and the at least one memory 164 and at least one processor 162 in the computing system 160 shown in FIG. 1.

In some implementations, the one or more processors may further generate a pre-process physical model to extract pre-process measurement results for the sample, where the pre-process physical model is generated based on the pre-process step measured signals for the one or more reference samples, and the pre-process step data includes the pre-process measurement results extracted from the pre-process physical model, e.g., as illustrated by the pre-process physical model 414 and the grey dotted line from the pre-process step measured signals 404 to the pre-process physical model 414 and the grey dotted line from the pre-process physical model 414 to the machine learning model 422 shown in FIG. 4. A means for generating a pre-process physical model to extract pre-process measurement results for the sample, where the pre-process physical model is generated based on the pre-process step measured signals for the one or more reference samples, and the pre-process step data includes the pre-process measurement results extracted from the pre-process physical model may be, e.g., the at least one processor 162 configured to implement one or more physical models, e.g., based on instructions for Model 164pm from the computer-readable program code 166 on non-transitory computer-usable storage medium, such as memory 164 shown in FIG. 1.

By way of example, in some implementations, the pre-process physical model may be generated further based on at least one of second measured signals obtained from a measurement pad and third measured signals obtained from a fault detection pad, e.g., as illustrated by the grey dotted line from the second measurement pad 406 to the pre-process physical model 414 and the grey dotted line from the fault detection pad 409 to the pre-process physical model 414 shown in FIG. 4.

In some implementations, the pre-process step data may include the pre-process step measured signals, e.g., as illustrated by the black dashed line from the pre-process step measured signals 404 to the machine learning model 422 shown in FIG. 4.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A method of characterizing a structure on a sample, comprising:
obtaining measured signals for the structure on the sample from a first metrology device;
extracting measurement results from a first physical model for the structure on the sample based on the measured signals; and
determining parameters of interest for the structure on the sample with a machine learning model based on the measurement results extracted from the first physical model, and further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample.

2. The method of claim 1, wherein the data from measured signals comprises one of at least one data channel comprising a measurement subsystem defined by at least one of a light source, an optical path directed by optical parts, a detector, or a combination thereof, and at least one data chunk comprising a subset of wavelengths, frequencies, angles, time span, or any combination thereof from a full data set provided by the at least one data channel.

3. The method of claim 1, wherein the machine learning model is generated based on measurement results extracted by the first physical model for one or more reference samples for the structure and at least one of reference data and design of experiment information, and at least one of: data from measured signals not used in generating the first physical model, second measured signals obtained for the one or more reference samples from the second metrology device, process parameters used to generate the one or more reference samples, APC parameters used to generate the one or more reference samples, context data for the one or more reference samples, and sensor data from production equipment used to generate the one or more reference samples.

4. The method of claim 1, wherein the measurement results are extracted from the first physical model for the structure on the sample further based on the second measured signals for the structure on the sample from the second metrology device.

5. The method of claim 1, wherein the measurement results that are extracted from the first physical model for the structure on the sample are further based on at least one of the process parameters, the APC parameters, the context data, and the sensor data from production equipment.

6. The method of claim 1, further comprising extracting second measurement results from a second physical model for the structure on the sample based on the second measured signals from the second metrology device, wherein the machine learning model determines the parameters of interest for the structure on the sample further based on the second measurement results extracted from the second physical model.

7. The method of claim 6, wherein the second measurement results are extracted from the second physical model for the structure on the sample further based on third measured signals for the structure on the sample from a third metrology device.

8. The method of claim 6, wherein the second measurement results are extracted from the second physical model for the structure on the sample further based on at least one of the process parameters, the APC parameters, the context data, and the sensor data from production equipment.

9. The method of claim 1, wherein the machine learning model determines the parameters of interest for the structure on the sample further based on the second measured signals from the second metrology device and further based on third measured signals for the structure on the sample from a third metrology device.

10. A computer system configured for characterizing a structure on a sample comprising:
at least one memory configured store measured signals, measurement results, a first physical model, a machine learning model, and parameters of interest for the structure; and
at least one processor coupled to the at least one memory, wherein the at least one processor is configured to:
obtain measured signals for the structure on the sample from a first metrology device;
extract measurement results from a first physical model for the structure on the sample based on the measured signals; and
determine parameters of interest for the structure on the sample with a machine learning model based on the measurement results extracted from the first physical model, and further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample.

11. The computer system of claim 10, wherein the data from measured signals comprises one of at least one data channel comprising a measurement subsystem defined by at least one of a light source, an optical path directed by optical parts, a detector, or a combination thereof, and at least one data chunk comprising a subset of wavelengths, frequencies, angles, time span, or any combination of thereof from a full data set provided by the at least one data channel.

12. The computer system of claim 10, wherein the machine learning model is generated based on measurement results extracted by the first physical model for one or more reference samples for the structure and at least one of reference data and design of experiment information, and at least one of: data from measured signals not used in generating the first physical model, second measured signals obtained for the one or more reference samples from the second metrology device, process parameters used to generate the one or more reference samples, APC parameters used to generate the one or more reference samples, context data for the one or more reference samples, and sensor data from production equipment used to generate the one or more reference samples.

13. The computer system of claim 10, wherein the measurement results are extracted from the first physical model for the structure on the sample further based on the second measured signals for the structure on the sample from the second metrology device.

14. The computer system of claim 10, wherein the measurement results that are extracted from the first physical model for the structure on the sample are further based on at least one of the process parameters, the APC parameters, the context data, and the sensor data from production equipment.

15. The computer system of claim 10, wherein the at least one processor is further configured to extract second measurement results from a second physical model for the structure on the sample based on the second measured signals from the second metrology device, wherein the machine learning model determines the parameters of interest for the structure on the sample further based on the second measurement results extracted from the second physical model.

16. The computer system of claim 15, wherein the second measurement results are extracted from the second physical model for the structure on the sample further based on third measured signals for the structure on the sample from a third metrology device.

17. The computer system of claim 15, wherein the second measurement results are extracted from the second physical model for the structure on the sample further based on at least one of the process parameters, the APC parameters, the context data, and the sensor data from production equipment.

18. The computer system of claim 10, wherein the machine learning model determines the parameters of interest for the structure on the sample further based on the second measured signals from the second metrology device and further based on third measured signals for the structure on the sample from a third metrology device.

19. A system configured for characterizing a structure on a sample, comprising:
means for obtaining measured signals for the structure on the sample from a first metrology device;
means for extracting measurement results from a first physical model for the structure on the sample based on the measured signals; and
means for determining parameters of interest for the structure on the sample with a machine learning model based on the measurement results extracted from the first physical model, and further based on at least one of: data from measured signals from the first metrology device not used in extracting the measurement results from the first physical model, second measured signals obtained for the structure on the sample from a second metrology device, process parameters used to generate the structure on the sample, Advanced Process Control (APC) parameters used to generate the structure on the sample, context data for the structure on the sample, and sensor data from production equipment used to generate the structure on the sample.

20. The system of claim 19, further comprising means for extracting second measurement results from a second physical model for the structure on the sample based on the second measured signals from the second metrology device, wherein the machine learning model determines the parameters of interest for the structure on the sample further based on the second measurement results extracted from the second physical model.
